(19) United States
(12) Patent Application Publication
(10) Pub. No.: US 2016/0232975 A1
(43) Pub. Date: Aug. 11, 2016

(54) SEMICONDUCTOR MEMORY DEVICE AND PROGRAMMING METHOD OF THE SAME

(71) Applicant: SK hynix Inc., Icheon-si Gyeonggi-do (KR)

(72) Inventor: Hae Soon OH, Cheongju-si Chungcheongbuk-do (KR)

(21) Appl. No.: 14/792,853

(22) Filed: Jul. 7, 2015

(30) Foreign Application Priority Data
Feb. 6, 2015 (KR) 10-2015-0018784

(51) Int. Cl. G11C 16/10; G11C 16/28; G11C 16/04

(52) U.S. Cl. CPC G11C 16/10; G11C 16/0483; G11C 16/28

(57) ABSTRACT

A semiconductor memory device may include a memory array including memory strings coupled between bit lines and a common source line. The semiconductor memory device may include a peripheral circuit coupled to the memory array through the bit lines. The peripheral circuit may be configured to generate a bit line voltage varied according to a temperature of the memory array and provide the bit line voltage to a selected bit line among the bit lines. The peripheral circuit may provide a program inhibit voltage to a non-selected bit line during a program operation.

### CROSS-REFERENCE TO RELATED APPLICATION

The present application claims priority to Korean patent application number 10-2015-0018784 filed on Feb. 6, 2015, in the Korean Intellectual Property Office, the entire disclosure of which is incorporated by reference herein.

### BACKGROUND

1. Technical Field

Various embodiments generally relate to a semiconductor memory device, and more particularly, to a 3D semiconductor memory device and a programming method of the same.

2. Related Art

Semiconductor memory devices have been developed with various structures to improve the degrees of integration of the semiconductor memory devices. For example, a three-dimensional (3D) semiconductor memory device has been suggested to improve the degree of integration of semiconductor memory devices.

The 3D semiconductor memory devices include memory cells stacked on a substrate along a channel layer. The 3D semiconductor memory devices may improve a degree of integration by increasing the number of stacks of the memory cells. The 3D semiconductor memory devices include a memory block having a different structure from that of a two-dimensional semiconductor memory device. Accordingly, in order to secure reliability of an operation, development of various techniques appropriate for the structure of the 3D semiconductor memory device has been desired.

### SUMMARY

In an embodiment, there may be provided a semiconductor memory device. The semiconductor memory device may include a memory array including memory strings coupled between bit lines and a common source line. The semiconductor memory device may include a peripheral circuit coupled to the memory array through the bit lines. The peripheral circuit may be configured to generate a bit line voltage varying according to a temperature of the memory array and may provide the bit line voltage to a selected bit line among the bit lines. The peripheral circuit may provide a program inhibit voltage to a non-selected bit line during a program operation.

In an embodiment, there may be provided a programming method of a semiconductor memory device. The programming method may include providing a memory array including memory strings coupled between bit lines and a common source line. The programming method may include providing a memory array including memory strings coupled between bit lines and a common source line. The programming method may include sensing a temperature of the memory array. The programming method may include generating a bit line voltage according to the sensed temperature and applying the bit line voltage to a selected bit line among the bit lines.

### BRIEF DESCRIPTION OF THE DRAWINGS

FIG. 1 is a block diagram illustrating a representation of an example of a semiconductor memory device according to an embodiment.

FIGS. 2A and 2B are circuit diagrams for describing a representation of an example of a memory string according to an embodiment.

FIG. 3 is a block diagram illustrating a representation of an example of a page buffer circuit according to an embodiment.

FIG. 4 is a flowchart for describing a representation of an example of a programming operation of the semiconductor memory device according to an embodiment.

FIGS. 5A and 5B are diagrams for describing a representation of an example of an operation of a program mode string connected to a selected bit line.

FIGS. 6A and 6B are diagrams for describing a representation of an example of an operation of a selection inhibit mode string coupled to a selected bit line.

FIGS. 7A and 7B are diagrams for describing a representation of an example of an operation of non-selection inhibit mode strings coupled to a non-selected bit line.

FIG. 8 is a configuration diagram illustrating a representation of an example of a memory system according to an embodiment.

FIG. 9 is a configuration diagram illustrating a representation of an example of a computing system according to an embodiment.

### DETAILED DESCRIPTION

Hereinafter, various examples of embodiments will be described with reference to the accompanying drawings. However, the embodiments are not limited to the embodiments to be disclosed below, but various forms different from each other may be implemented.

Various embodiments may provide a semiconductor memory device capable of improving the reliability of a program operation, and a programming method of the same.

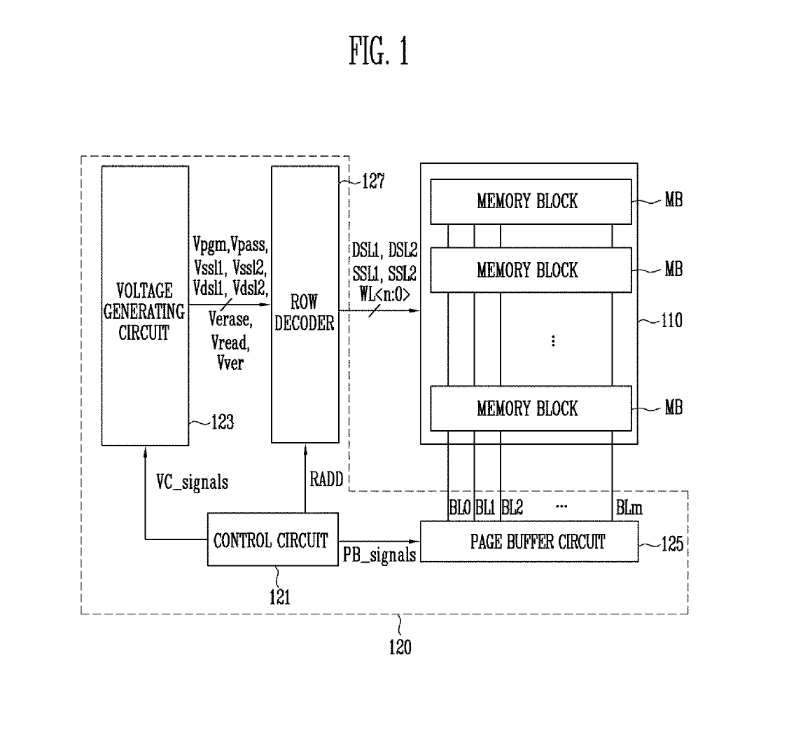

FIG. 1 is a block diagram illustrating a representation of an example of a semiconductor memory device according to an embodiment.

Referring to FIG. 1, a semiconductor memory device may include a memory array 110 and a peripheral circuit 120.

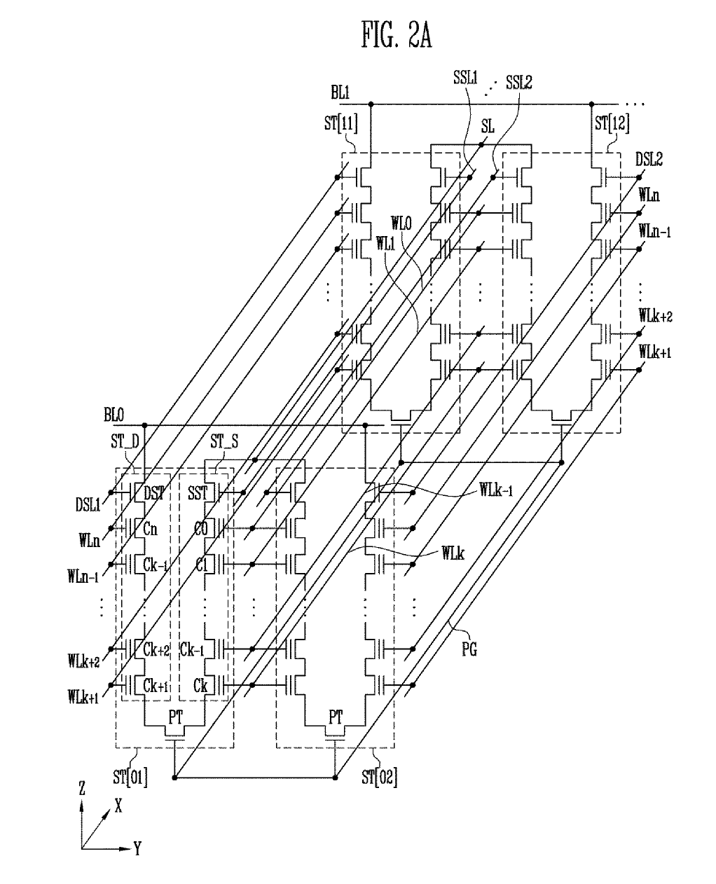

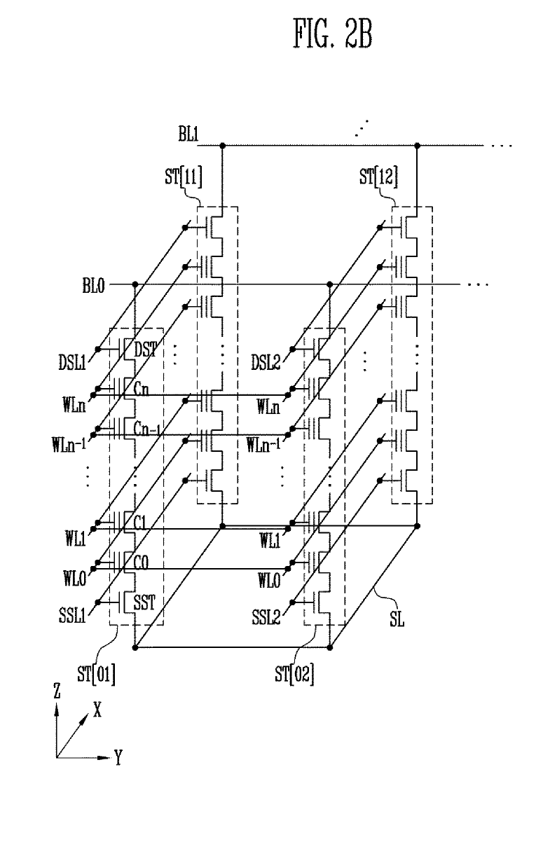

The memory array 110 includes a plurality of memory blocks MB. Each of the memory blocks 110 includes a plurality of memory strings. A structure of each of the memory strings will be described with reference to FIGS. 2A and 2B below. The memory blocks MB are connected to the peripheral circuit 120 through bit lines BL0 to BLm. The memory blocks MB are connected to the peripheral circuit 120 through select lines DSL1, DLS2, SSL1, and SSL2, and word lines WL<n:0>.

The peripheral circuit 120 is configured to perform an operation related to data input/output. For example, the peripheral circuit 120 is configured to perform a program operation, a verification operation, an erase operation, and a read operation. In order to perform the program operation, the verification operation, the erase operation, and the read operation, the peripheral circuit 120 may include a control circuit 121, a voltage generating circuit 123, a page buffer circuit 125, and a row decoder 127. The peripheral circuit 120 is configured to selectively output operation voltages, for example but not limited to, Vpgm, Vpass, Vssl1, Vssl2, Vdsl1, Vdsl2, Verase, Vread, and Vver to a selected memory block under the control of the control circuit 121. The peripheral circuit 120 is configured to control precharge/discharge of the bit lines BL0 to BLm or sense a current flow of the bit lines BL0 to BLm. Each constituent element of the peripheral circuit 120 will be described below.

The control circuit 121 is coupled to the voltage generating circuit 123, the page buffer circuit 125, and the row decoder 127. The control circuit generates and outputs voltage control signals VC_signals for controlling the voltage generating circuit 123. The control circuit generates and outputs page buffer control signals PB_signals for controlling the page buffer circuit 125. The control circuit generates and outputs a row address RADD for controlling the row decoder 127. The control circuit may generate and output the voltage control signals VC_signals, page buffer control signals PB_signals, and the row address RADD during the program operation, the verification operation, the erase operation, and the read operation of the semiconductor memory device. The control circuit 121 may operate in response to a command signal input from the outside.

The voltage generating circuit 123 generates the operation voltages, Vpass, Vssl1, Vssl2, Vdsl1, Vdsl2, Verase, Vread, and Vver with desired levels. The voltage generating circuit 123 may generate the operation voltages, Vpass, Vssl1, Vssl2, Vdsl1, Vdsl2, Verase, Vread, and Vver with desired levels in response to the voltage control signals VC_signals output from the control circuit 121. The voltage generating circuit 123 may generate a program voltage Vpgm, a pass voltage Vpass, source select line voltages Vssl1 and Vssl2, and drain select line voltage Vdsl1 and Vdsl2 necessary for the program operation of the semiconductor memory device with desired levels. The voltage generating circuit 123 may generate an erase voltage Verase necessary for the erase operation of the semiconductor memory device with a desired level. The voltage generating circuit 123 may generate a read voltage Vread necessary for the read operation of the semiconductor memory device with a desired level. The voltage generating circuit 123 may generate a verification voltage Vver necessary for the verification operation of the semiconductor memory device with a desired level.

The row decoder 127 is coupled with the memory blocks MB of the memory array 110 through select lines DSL1, DSL2, SSL1, and SSL2 and the word lines WL<n:0>. The row decoder 127 transmits the operation voltages Vpgm, Vpass, Vssl1, Vssl2, Vdsl1, Vdsl2, Verase, Vread, and Vver to the selected memory block of the memory array 110. The row decoder 127 transmits the operation voltages Vpgm, Vpass, Vssl1, Vssl2, Vdsl1, Vdsl2, Verase, Vread, and Vver to the selected memory block of the memory array 110 in response to the row address RADD output from the control circuit 121.

The page buffer circuit 125 is coupled with the memory blocks MB of the memory array 110 through the bit lines BL0 to BLm. The page buffer circuit 125 may selectively precharge the bit lines BL0 to BLm in response to the page buffer control signals PB_signals output from the control circuit 121. The page buffer circuit 125 may selectively precharge the bit lines BL0 to BLm according to data input from the outside during the program operation. The page buffer circuit 125 may sense threshold voltages of the memory cells by using the potentials of the bit lines BL0 to BLm during the read operation and the verification operation.

The page buffer circuit 125 may sense a temperature of the memory array 110 and generate a bit line voltage varied according to the temperature of the memory array 110 during the program operation. The page buffer circuit 125 configured to sense a temperature of the memory array 110 and to generate a bit line voltage varied according to the temperature of the memory array 110 during the program operation may improve reliability of the program operation. For example, the page buffer circuit 125 may selectively provide the bit line voltage varied according to the temperature to the bit lines BL0 to BLm according to the data input from the outside.

FIGS. 2A and 2B are circuit diagrams for describing a representation of an example of the memory string according to an embodiment.

Referring to FIGS. 2A and 2B, each of the memory blocks may include a plurality of memory strings ST[01] to ST[12] coupled between the bit lines BL0 and BL1 and a common source line SL. The bit lines BL0 and BL1 may be disposed on a different plane from that of the common source line SL. Each of the memory strings ST[01] to ST[12] includes a drain select transistor DST coupled to any one of the bit lines BL0 and BL1. Each of the memory strings ST[01] to ST[12] includes a source select transistor SST coupled to the common source line SL. Each of the memory strings ST[01] to ST[12] includes memory cells C0 to Cn serially coupled between the source select transistor SST and the drain select transistor DST.

The memory cells C0 to Cn may be three-dimensionally arranged in different first to third directions (X, Y, and Z). The memory cells C0 to Cn are serially coupled in the unit of the memory strings ST[01] to ST[12].

Each of the memory strings ST[01] to ST[12] may be formed in various forms, such as, for example but not limited to, a U-shape, a W-shape, and a straight shape.

For example, as illustrated in FIG. 2A, each of the memory strings ST[01] to ST[12] may be formed in a U-shape. Referring to FIG. 2A, each of the memory strings ST[01] to ST[12] may include the drain select transistor DST and the source select transistor SST disposed on the same plane. In this example, each of the memory strings ST[01] to ST[12] may further include a pipe transistor PT disposed on a different plane from that of the drain select transistor DST and the source select transistor SST. The memory cells C0 to Cn of each of the memory strings ST[01] to ST[12] may be divided into drain side memory cells Ck+1 to Cn configuring a drain side string ST_D and source side memory cells C0 to Ck configuring a source side string ST_S. The drain side memory cells Ck+1 to Cn are stacked between the pipe transistor PT and the drain select transistor DST, and are serially coupled. The source side memory cells C0 to Ck are stacked between the pipe transistor PT and the source select transistor SST, and are serially coupled.

The pipe transistor PT includes a gate coupled to the pipe gate PG, and is controlled by a voltage applied to the pipe gate PG. The pipe transistor PT performs an operation of electrically connecting a channel of the source side string ST_S and a channel of the drain side string ST_D included in the selected memory block.

Gates of the source side memory cells C0 to Ck are coupled to source side word lines WL0 to WLk stacked between the pipe gate PG and the common source line SL. The source side memory cells C0 to Ck are controlled by a voltage applied to the source side word lines WL0 to WLk. The adjacent memory strings ST[01] to ST[12] within one memory block may share the source side word lines WL0 to WLk.

The source select transistor SST includes a gate coupled to the source select line SSL1 or SSL2, and is controlled by a voltage applied to the source select line SSL1 or SSL2. The source select transistor SST controls a connection or a block of the memory string (for example, ST[01]) corresponding to the source select transistor SST and the common source line SL. The source select line SSL1 or SSL2 is disposed between the source side word lines WL0 to WLk and the common source line SL.

Gates of the drain side memory cells Ck+1 to Cn are coupled to the drain side word lines WLK+1 to WLn stacked between the pipe gate PG and the bit lines BL0 and BL1, respectively. The drain side memory cells Ck+1 to Cn are controlled by a voltage applied to the drain side word lines WLk+1 to WLn.

The drain select transistor DST includes a gate coupled to the drain select line DSL1 or DSL2, and is controlled by a voltage applied to the drain select line DSL1 or DSL2. The drain select transistor DST controls a connection or a block of the memory string (for example, ST[01]) corresponding to the drain select transistor DST and the bit line (for example, BL0) corresponding to the source select transistor SST corresponding to the drain select transistor DST. The drain select line DSL1 or DSL2 is disposed between the drain side word lines WLk+1 to WLn and the bit lines BL0 and BL1.

In an embodiment, each of the memory strings ST[01] to ST[12] may be formed in a straight type as illustrated in FIG. 2B. Referring to FIG. 2B, each of the memory strings ST[01] to ST[12] may include the drain select transistor DST and the source select transistor SST disposed on the different planes. In this example, the memory cells C0 to Cn of each of the memory strings ST[01] to ST[12] are serially coupled between the source select transistor SST and the drain select transistor DST and serially stacked.

Gates of the memory cells C0 to Cn are coupled to the word lines WL to WLn stacked between the bit lines BL0 and BL1 and the common source line SL. The memory cells C0 to Cn are controlled by a voltage applied to the word lines WL0 to WLn. Each of the word lines WL0 to WLn within one memory block may include line parts extended in a predetermined direction (for example, an X-direction) and a connection part for coupling one sides of the line parts. Otherwise, each of the word lines WL0 to WLn may be formed in a plate type. Accordingly, the memory strings ST[01] to ST[12] within one memory block may share the word lines WL0 to WLn.

The source select transistor SST includes a gate coupled to the source select line SSL1 or SSL2, and is controlled by a voltage applied to the source select line SSL1 or SSL2. The source select transistor SST controls a connection or a block of the memory string (for example, ST[01]) corresponding to the source select transistor SST and the common source line SL. The source select line SSL1 or SSL2 is disposed between the word lines WL0 to WLn and the common source line SL.

The drain select transistor DST includes a gate coupled to the drain select line DSL1 or DSL2, and is controlled by a voltage applied to the drain select line DSL1 or DSL2. The drain select transistor DST controls a connection or a block of the memory string (for example, ST[01]) corresponding to the drain select transistor DST and the bit line (for example, BL0) corresponding to the source select transistor SST corresponding to the drain select transistor DST. The drain select line DSL1 or DSL2 is disposed between the word lines WL0 to WLn and the bit lines BL0 and BL1.

Referring to FIGS. 2A and 2B, in the semiconductor memory device according to the various examples of embodiments, the plurality of memory strings may be commonly coupled to each of the bit lines BL0 and BL1 within one memory block. For example, two or more memory strings ST[01] and ST[02] may be commonly coupled to a predetermined bit line BL0. The number of memory strings commonly coupled to each of the bit lines BL0 and BL1 within one memory block may be variously changed according to a design.

The word lines WL0 to WLn may be extended in the direction X crossing the extended direction Y of the bit lines BL0 and BL1 to be commonly coupled to the two or more memory strings. The number of memory strings commonly coupled to each of the word lines WL0 to WLn may be variously changed according to a design.

The drain select line DSL1 or DSL2 and the source select line SSL1 or SSL2 may be extended in the direction X crossing the extended direction Y of the bit lines BL0 and BL1 to be commonly coupled to two or more memory strings. The number of memory strings coupled to the drain select line DSL1 or DSL2 and the source select line SSL1 or SSL2 may be variously changed according to a design.

The number of drain select lines DSL1 and DSL2, the source select lines SSL1 and SSL2, the word lines WL0 to WLn, the bit lines BL0 and BL1, and the memory strings ST[01] to ST[12] configuring one memory block may be variously changed according to a design. The number of memory cells C0 to Cn configuring each of the memory strings ST[01] to ST[12] may be variously changed according to a design.

The program operation, the verification operation, and the read operation of the semiconductor memory device according to the various embodiments may be performed in a unit of a page within a selected memory block. One page is formed of memory cells coupled to one word line (for example, WL0) among the memory cells of a selected memory block.

In both a three-dimensional (3D) semiconductor memory device and a two-dimensional (2D) semiconductor memory device, the bit lines coupled to a selected memory block during the program operation may be divided into a selected bit line and a non-selected bit line. In both the 3D semiconductor memory device and the 2D semiconductor memory device, only a program inhibit mode string is coupled to the non-selected bit line. Hereinafter, the program inhibit mode string coupled to the non-selected bit line is defined as a non-selection inhibit mode string. A channel boosting scheme may be used in order to prevent the memory cells coupled to the non-selection inhibit mode string from being programmed. A mode of the memory string coupled to the selected bit line is different in the 3D semiconductor memory device and the 2D semiconductor memory device.

In the 2D semiconductor memory device, only a program mode string including a memory cell, which is a target of the programming, is coupled to a selected bit line. Accordingly, the 2D semiconductor memory device may maintain a state of the drain select transistor coupled to the selected bit line in a turn-on state so that the selected bit line may be coupled with the channel of the program mode string during the program operation.

In the 3D semiconductor memory device, the program inhibit mode string, as well as the program mode string, may be coupled. Hereinafter, the program inhibit mode string coupled to the selected bit line is defined as a selection inhibit mode string. Referring to FIGS. 2A and 2B, when, for example, a first memory cell C1 of a first memory string ST[01] is desired to be programmed, a first bit line BL0 coupled to the first memory string ST[01] is selected during the program operation. The first bit line BL0 is also coupled to a second memory string ST[02] that is the selection inhibit mode string, as well as the first memory string ST[01] that is the program mode string.

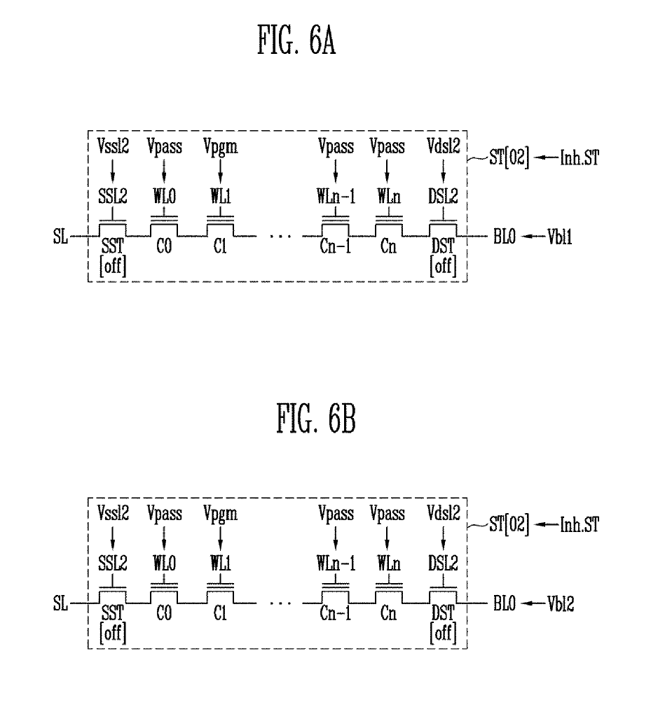

A channel of the first memory string ST[01] that is the program mode string and the selected first bit line BL0 may be coupled with each other through the drain select transistor DST turned on by a voltage applied to the first drain select line DSL1. A channel of the second memory string ST[02] that is the selection inhibit mode string and the selected first bit line BL0 are electrically blocked through the drain select transistor DST turned off by a voltage applied to the second drain select line DSL2. Accordingly, the 3D semiconductor memory device may prevent the memory cells coupled to the selection inhibit mode string from being programmed by using the channel boosting scheme. The channel boosting scheme of the selection inhibit mode string will be described below with reference to FIGS. 6A and 6B.

As described above, a selected bit line of the 2D semiconductor memory device is coupled only to an on-state drain select transistor. By contrast, a selected bit line of the 3D semiconductor memory device is coupled to an on-state drain select transistor and an off-state drain select transistor. Accordingly, it is relatively more difficult for the 3D semiconductor memory device to control a program disturbance, compared to the 2D semiconductor memory device.

In order to improve the program disturbance, a bit line voltage applied to a selected bit line may be increased during the program operation of the 3D semiconductor memory device. When the bit line voltage applied to the selected bit line is high, a body effect of the drain select transistor coupled to the selected bit line is increased, thereby decreasing a leakage current of an off-state drain select transistor connected to the selected bit line. As described above, the selected bit line of the 3D semiconductor memory device is coupled to an on-state drain select transistor, as well as the off-state drain select transistor. Accordingly, when the bit line voltage applied to the selected bit line is increased during the program operation, it may be possible to simultaneously increase a body effect of the off-state drain select transistor coupled to the selected bit line and a body effect of the on-state drain select transistor coupled to the selected bit line. A state of the on-state drain select transistor may be varied according to a temperature of the memory array by an increase in the body effect. More particularly, when, for example, a temperature of the memory array exceeds a room temperature (20° C. to 25° C.), the on-state drain select transistor may maintain the on-state. For example, when a temperature of the memory array is a low temperature equal to or lower than the room temperature, the on-state drain select transistor may be turned off. In this example, a memory cell, which is a target for programming, of the program mode string may not be programmed.

In an example of an embodiment, the bit line voltage applied to the selected bit line is varied according to a temperature of the memory array. Accordingly, in the example of the embodiment, even though a temperature of the memory array is changed, the drain select transistor of the program mode string may be maintained in the on-state. In an example of the embodiment, it may be possible to maintain channel boosting efficiency of the selection inhibit mode string by decreasing a phenomenon that a leakage current is generated in the drain select transistor of the selection inhibit mode string.

FIG. 3 is a block diagram illustrating a representation of an example of the page buffer circuit according to an embodiment.

Referring to FIG. 3, the page buffer circuit 125 includes page buffers PB0 to PBm coupled to the bit lines B0 to BLm, respectively, and a temperature sensing circuit 210 coupled to the page buffers PB0 to PBm.

Data to be programmed in the memory cell array 110 (see FIG. 1) or data read from the memory cell 110 (see FIG. 1) is stored in each of the page buffers PB0 to PBm. Each of the page buffers PB0 to PBm may include a precharge unit 220 for applying a program inhibit voltage or a bit line voltage varied according to a temperature of the bit lines BL0 to BLm according to a stored data value during the programming.

The temperature sensing circuit 210 senses a temperature of the memory cell array 110 (see FIG. 1) and may generate temperature sensing information. The temperature sensing information generated by the temperature sensing circuit 210 is supplied to the precharge unit 220 of each of the page buffers PB0 to PBm. When, for example, the temperature of the memory cell array 110 (see FIG. 1) is equal to or lower than a reference temperature, the temperature sensing circuit 210 may generate temperature sensing information of first data. When, for example, the temperature of the memory cell array 110 (see FIG. 1) is higher than the reference temperature, the temperature sensing circuit 210 may generate temperature sensing information of second data. During the programming, the precharge unit 220 applies a program inhibit voltage, which maintains a predetermined value regardless of the temperature sensing information, of the non-selected bit line. During the programming, the precharge unit 220 applies a bit line voltage varied according to the temperature sensing information of the selected bit line. For example, the precharge unit 220 may apply a first bit line voltage to the selected bit line according to the temperature sensing information of the first data, and apply a second bit line voltage higher than the first bit line voltage of the selected bit line according to the temperature sensing information of the second data.

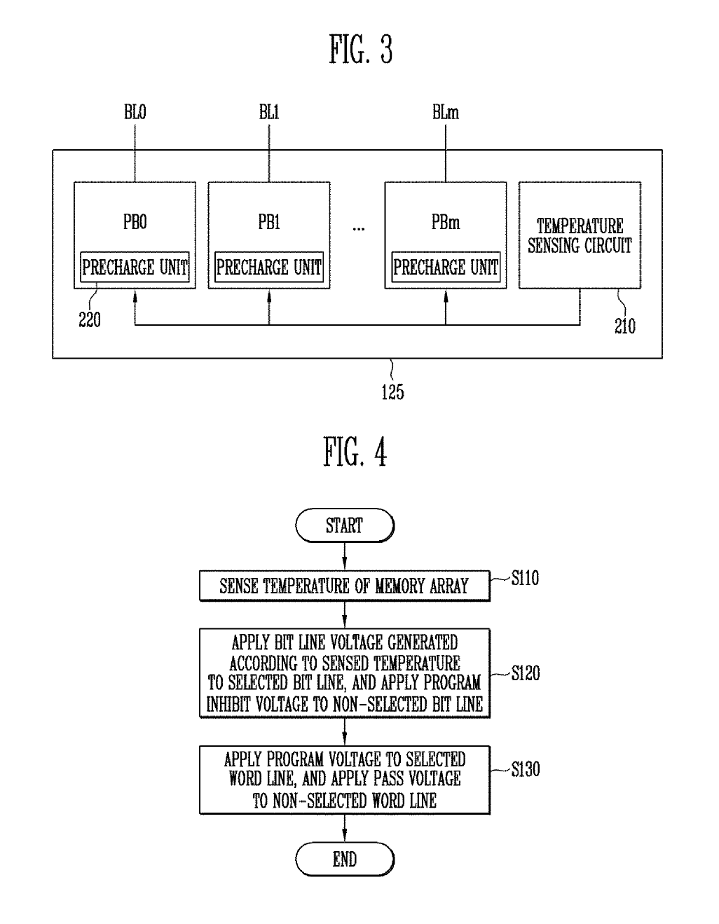

Hereinafter, the program operation of the semiconductor memory device according to an example of an embodiment will be described in more detail with reference to FIGS. 4 to 7B.

FIG. 4 is a flowchart for describing a representation of an example of a programming operation of the semiconductor memory device according to an embodiment.

Referring to FIG. 4, for a program operation, a temperature of the memory array configuring the semiconductor memory device according to an example of an embodiment is sensed (S110). The memory array may include the memory cells, which are three-dimensionally arranged, as described with reference to FIGS. 2A and 2B.

A bit line voltage may be generated according to the sensed temperature, and a bit line voltage varied according to the sensed temperature is applied to a selected bit line among the bit lines (S120). A program inhibit voltage may be applied to the non-selected bit line while the bit line voltage is applied to the selected bit line. In this example, a turn-off voltage may be applied to the source select lines, and a ground voltage may be applied to the common course line. In this example, a turn-on voltage may be applied to the drain select line coupled to the program mode string among the drain select lines, and the turn-off voltage may be applied to the remaining drain select lines.

The program inhibit voltage is set with a level capable of causing channel boosting of a first non-selection inhibit mode string coupled to the drain select line, to which the turn-on voltage is applied, among the non-selection prohibition mode strings. For example, the program inhibit voltage may be set with a level equal to or higher than that of the turn-on voltage applied to the drain select line. The bit line voltage may be set with a level lower than that of the program inhibit voltage and lower than that of the turn-on voltage applied to the drain select line to prevent the channel boosting of the program mode string.

According to the aforementioned voltage condition, a channel of the program mode string may be coupled to the selected bit line, and the bit line voltage varied according to the sensed temperature may be applied to the drain select line of the program mode string.

When, for example, the sensed temperature is equal to or lower than a reference temperature, a first bit line voltage is generated, and when, for example, the sensed temperature is higher than the reference temperature, a second bit line voltage different from the first bit line voltage is generated. The reference temperature may be a room temperature. The room temperature may include a range from 20° C. to 25° C. Hereafter, a temperature range equal to or lower than the reference temperature is referred to as a low temperature, and a temperature range higher than the reference temperature is referred to as a high temperature.

The first and second bit line voltages may be set with levels lower than that of the program inhibit voltage to prevent the channel boosting of the program mode string. The second bit line voltage may be set with a level higher than that of the first bit line voltage to improve a body effect of the drain select transistor. For example, the first bit line voltage may be a ground voltage of 0 V. The second bit line voltage may be larger than 0.1 V and smaller than 2 V.

The select bit line, to which the first bit line voltage or the second bit line voltage is applied, is connected to an on-state drain select transistor of the program mode string and an off-state drain select transistor of the selection inhibit mode string.

When the first bit line voltage is applied to the selected bit line at a low temperature similar to an embodiment, the body effect of the off-state drain select transistor is not increased. The off-state drain select transistor has a slight leakage current variation at a low temperature. Accordingly, even though the body effect of the off-state drain select transistor is not increased at a low temperature, a leakage current characteristic of the off-state drain select transistor may be maintained at a low temperature.

The leakage current characteristic of the off-state drain select transistor is sharply degraded at a high temperature. In an embodiment, it may be possible to increase the body effect of the off-state drain select transistor by applying a second bit line voltage with a level higher than that of the first bit line voltage to the selected bit line at a high temperature. Accordingly, in an embodiment, it may be possible to decrease a leakage current of the off-state drain select transistor at a high temperature.

The on-state drain select transistor may maintain the on-state even though the body effect is increased at a high temperature. Accordingly, even though the second bit line voltage with the level increasing the body effect of the drain select transistor is applied to the selected bit line at a high temperature, it may be possible to maintain the on-state of the drain select transistor.

When the body effect of the drain select transistor is increased to a low temperature, the on-state drain select transistor may be changed to the off state. In an embodiment, it may be possible to prevent the on-state drain select transistor from being state-changed at a low temperature by applying the first bit line voltage with the level lower than that of the second bit line voltage to the selected bit line to prevent the body effect of the on-state drain select transistor from increasing at a low temperature.

In an embodiment, a bit line voltage applied to a selected bit line is varied according to a temperature of the memory array. Accordingly, in an embodiment, it may be possible to simultaneously improve a state change of an on-state drain select transistor coupled to a selected bit line and a leakage current characteristic change of an off-state drain select transistor. As a result, in an embodiment, it may be possible to stably secure the program operation of the 3D semiconductor memory device.

After the bit line voltage and the program inhibit voltage are applied to the bit lines, a program voltage is applied to the selected word line, and a pass voltage is applied to the non-selected word line (S130). The program voltage has a large level enough to cause FN tunneling from the channel of the memory string, and the pass voltage has a level larger than that of a threshold voltage of a memory cell and smaller than that of the program voltage. When the program voltage and the pass voltage are applied, a potential difference large enough to cause FN tunneling between the channel of the program mode string and the gate of a memory cell, which is a target for programming, coupled to the selected word line, is generated, so that the memory cell, which is the target for programming, is programmed. Further, the channel of the selection inhibit mode string and the channel of the non-selection inhibit mode string are boosted by the program voltage and the pass voltage in a floating state. Accordingly, the programming of the memory cells coupled to the selection inhibit mode string and the non-selection inhibit mode string is inhibited.

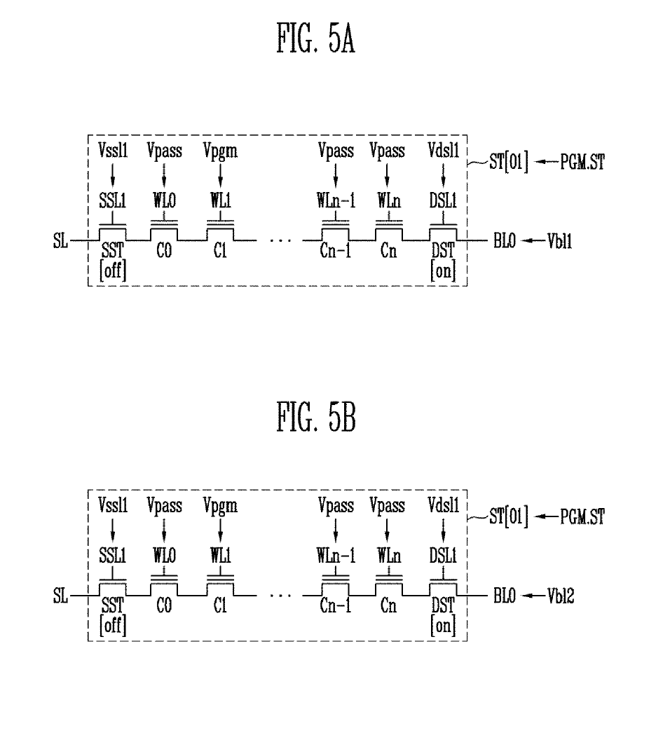

Hereinafter, a string operation for each mode will be described with reference to FIGS. 5A to 7B. Hereinafter, the string operation will be described based on a example where the first memory cell C1 of the first memory string ST[01] coupled to the first bit line BL0 is programmed as an example. Hereinafter, a level of each of the voltages is the same as that described with reference to FIG. 4.

FIGS. 5A and 5B are diagrams for describing a representation of an example of an operation of a program mode string coupled to a selected bit line. FIG. 5A illustrates a voltage applied to a program mode string at a low temperature during the program operation, and FIG. 5B illustrates a voltage applied to a program mode string at a high temperature during the program operation.

Referring to FIGS. 5A and 5B, when a program mode string PGM.ST coupled to the selected first bit line BL0 is the first memory string ST[01], a first bit line voltage Vbl1 or a second bit line voltage Vbl2 is applied to the selected first bit line BL0 according to a temperature of the memory array during the program operation. When, for example, a temperature of the memory array is a low temperature, the first bit line voltage Vbl1 is applied to the selected first bit line BL0. When, for example, a temperature of the memory array is a high temperature, the second bit line voltage Vbl2 is applied to the selected first bit line BL0.

The voltages applied to the first source select line SSL1, the first drain select line DSL1, and the word lines WL0 to WLn coupled to the first memory string ST[01] of the program mode will be described below.

A turn-off voltage Vssl1 is applied to the first source select line SSL1, and a turn-on voltage Vdsl1 is applied to the first drain select line DSL1. The program voltage Vpgm is applied to the selected word line WL1 among the word lines WL0 to WLn, and the pass voltage Vpass is applied to the non-selected word lines WL0, WLn−1, and WLn.

Under the aforementioned condition, the source select transistor SST of the first memory string ST[01] is turned off, and the non-selected memory cells C0, Cn−1, and Cn are turned on, and the drain select transistor DST is turned on. The first bit line voltage Vbl1 of a lower level than that of the second bit line voltage Vbl2 is applied to the first bit line BL0 coupled to the drain select transistor DST of the first memory string ST[01] at a low temperature, so that the on-state of the drain select transistor DST may be maintained. Since the turn-on state of the drain select transistor DST is maintained, a channel of the first memory string ST[01] may be coupled to the selected first bit line BL0. The bit line voltage applied to the selected first bit line BL0 is set to be low to not cause channel boosting, and the program voltage Vpgm is set to be high to cause FN tunneling. Under the voltage condition, a high potential difference enough to cause the FN tunneling between the channel of the first memory string ST[01] and the gate of the first memory cell C1 is formed, so that the first memory cell C1 of the first memory string ST[01] may be programmed.

FIGS. 6A and 6B are diagrams for describing a representation of an example of an operation of a selection inhibit mode string coupled to a selected bit line. FIG. 6A illustrates a voltage applied to a selection inhibit mode string at a low temperature during the program operation, and FIG. 6B illustrates a voltage applied to a selection inhibit mode string at a high temperature during the program operation.

Referring to FIGS. 6A and 6B, the first bit line voltage Vbl1 or the second bit line voltage Vbl2 is applied to the selected first bit line BL0 according to a temperature of the memory array during the program operation substantially identical to the description with reference to FIGS. 5A and 5B. The second memory string ST[02], which is coupled to the selected first bit line BL0 and is a selection inhibit mode string Inh.ST, is coupled to the second drain select line DSL2 and the second source select line SSL2. The second drain select line DSL2 may be separated from the first drain select line DSL1 illustrated in FIGS. 5A and 5B and be separately controlled. The second source select line SSL2 may be separated from the first source select line SSL1 illustrated in FIGS. 5A and 5B and be separately controlled.

The voltages applied to the second source select line SSL2, the second drain select line DSL2, and the word lines WL0 to WLn coupled to the second memory string ST[02] of the selection inhibit mode will be described below.

The turn-off voltages Vssl1 and Vdsl2 are applied to the second source select line SSL2 and the second drain select line DSL2, respectively. The program voltage Vpgm is applied to the selected word line WL1 among the word lines WL0 to WLn, and the pass voltage Vpass is applied to the non-selected word lines WL0, WLn−1, and WLn.

Under the aforementioned condition, the source select transistor SST and the drain select transistor DST of the second memory string ST[02] are turned off. Therefore, the channel of the second memory string ST[02] is electrically blocked from the selected first bit line BL0 to be in a floating state. A channel potential of the second memory string ST[02] in the floating state may be boosted by the pass voltage Vpass and the program voltage Vpgm. Accordingly, the programming of the second memory cell C1 of the second memory string ST[02] coupled to the selected word line WL1 may be prevented. The reason is that a high potential difference enough to cause the FN tunneling is not formed between the channel of the second memory string ST[02] having the boosted potential and the gate of the second memory cell C1, to which the program voltage Vpgm is applied.

In order to improve program inhibit efficiency of the second memory string ST[02], boosting efficiency of the second memory string ST[02] needs to be maintained. To this end, in an embodiment, a leakage current of the drain select transistor DST is controlled at a high temperature so that the turn-off state of the drain select transistor DST of the second memory string ST[02] may be maintained during the program operation. In an embodiment, the second bit line voltage Vbl2 having a higher level than that of the first bit line Vbl1, which is applied to the selected first bit line BL0 at a low temperature, is applied to decrease a leakage current of the drain select transistor DST by increasing the body effect of the drain select transistor DST at a high temperature.

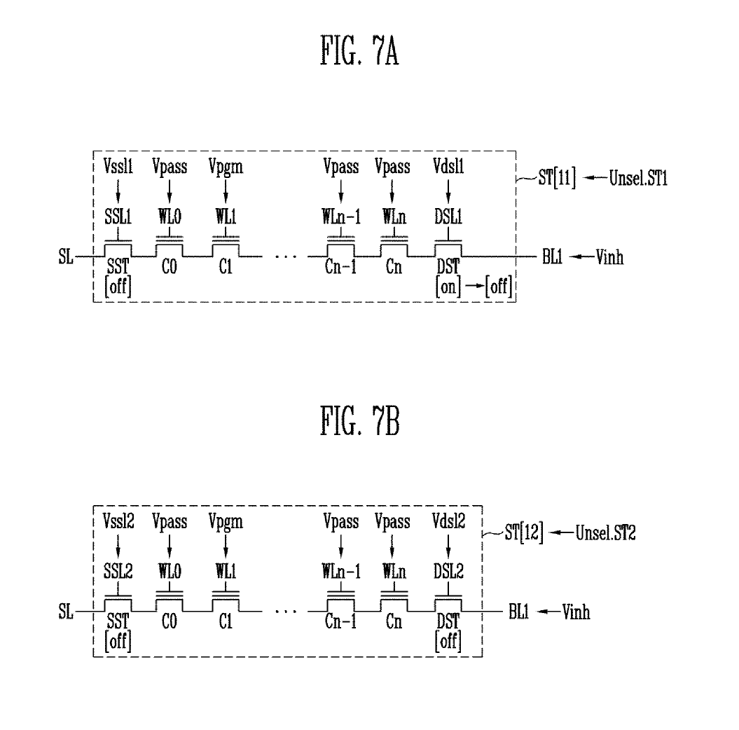

FIGS. 7A and 7B are diagrams for describing a representation of an example of an operation of non-selection inhibit mode strings coupled to a non-selected bit line.

Referring to FIGS. 7A and 7B, a program inhibit voltage Vinh is applied to a non-selected second bit line BL1 during the program operation. The non-selection prohibition mode strings coupled to the non-selected second bit line BL1 may be divided into a first non-selection inhibit mode string Unsel.ST1 and a second non-selection inhibit mode string Unsel.ST2. It may be defined that the first non-selection inhibit mode string Unsel.ST1 is coupled to the first drain select line DSL1 and the first source select line SSL1 coupled to the program mode string similar to a third memory string ST[11]. It may be defined that the second non-selection inhibit mode string Unsel.ST2 is coupled to the second drain select line DSL2 separated from the program mode string, similar to a fourth memory string ST[12]. The second non-selection prohibition mode string Unsel.ST2 may be coupled to the second source select line SSL2 separated from the program mode string.

The voltages applied to the first source select line SSL1, the first drain select line DSL1, the second source select line SSL2, the second drain select line DSL2, and the word lines WL0 to WLn have been described with reference to FIGS. 5A and 6B.

Referring to FIG. 7A, a source select transistor SST of the third memory string ST[11] is turned off, and a drain select transistor thereof is turned on. The program inhibit voltage Vinh applied to the second bit line BL1 is charged in a channel of the third memory string ST[11] through the turned-on drain select transistor DST. When, for example, a channel potential of the third memory string ST[11] is charged by a threshold voltage difference between the program inhibit voltage Vinh and the drain select transistor DST, the drain select transistor DST of the third memory string ST[11] is shut off. Accordingly, the channel of the third memory string ST[11] is electrically blocked from the non-selected second bit line BL1 to be in a floating state. A channel potential of the third memory string ST[11] in the floating state may be boosted by the pass voltage Vpass and the program voltage Vpgm. Accordingly, the programming of the third memory cell C1 of the third memory string ST[11] coupled to the selected word line WL1 may be prevented. The reason may be that a high potential difference enough to cause the FN tunneling is not formed between the channel of the third memory string ST[11] having the boosted potential and the gate of the third memory cell C1, to which the program voltage Vpgm is applied.

Referring to FIG. 7B, under the aforementioned condition, the source select transistor SST and the drain select transistor DST of the fourth memory string ST[12] are turned off. Accordingly, the channel of the fourth memory string ST[12] may be electrically blocked from the non-selected second bit line BL1 to be in a floating state. A channel potential of the fourth memory string ST[12] in the floating state may be boosted by the pass voltage Vpass and the program voltage Vpgm. Accordingly, the programming of the fourth memory cell C1 of the fourth memory string ST[12] coupled to the selected word line WL1 may be prevented. The reason is that a high potential difference enough to cause the FN tunneling is not formed between the channel of the fourth memory string ST[12] having the boosted potential and the gate of the fourth memory cell C1, to which the program voltage Vpgm is applied.

In an embodiment, it may be possible to improve reliability of the program operation by varying a bit line voltage provided to a selected bit line according to a temperature of the memory array.

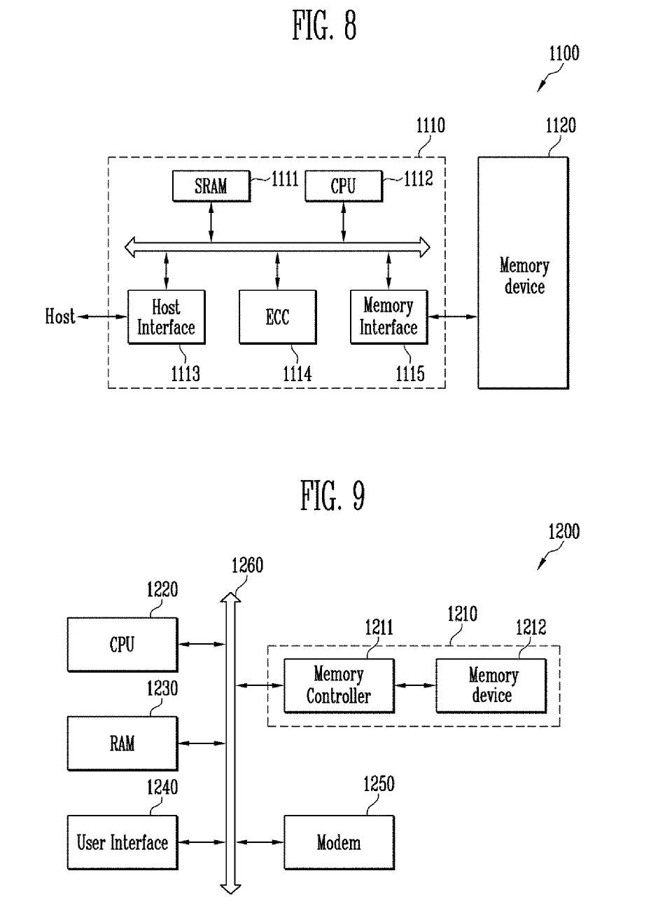

FIG. 8 is a configuration diagram illustrating a representation of an example of a memory system according to an embodiment.

Referring to FIG. 8, a memory system 1100 according to an embodiment may include a memory device 1120 and a memory controller 1110.

The memory device 1120 may be configured to be identical to the semiconductor memory device of FIG. 1. The memory device 1120 may include the memory array described with reference to FIGS. 2A and 2B, and the page buffer circuit described with reference to FIG. 3. A program operation of the memory device 1120 may be controlled by the method described with reference to FIGS. 4 to 7B. Further, the memory device 1120 may be a multi-chip package formed of a plurality of flash memory chips.

The memory controller 1110 may be configured to control the memory device 1120, and may include an SRAM 1111, a CPU 1112, a host interface 1113, an ECC 1114, and a memory interface 1115. The SRAM 1111 is used as an operational memory of the CPU 1112. The CPU 1112 performs a general control operation for a data exchange of the memory controller 1110. The host interface 1113 includes a data exchange protocol of a host coupled with the memory system 1100. The ECC 1114 detects and corrects an error included in data read from the memory device 1120, and the memory interface 1115 performs interfacing with the memory device 1120. In addition, the memory controller 1110 may further include an ROM and the like for storing code data for interfacing with the host.

As described above, the memory system 1100 including the aforementioned configuration may be a memory card or a Solid State Disk (SSD) in which the memory device 1120 is combined with the memory controller 1110. For example, when the memory system 1100 is the SSD, the memory controller 1110 may communicate with an external device (for example, a host) through one of various interface protocols, such as USB, MMC, PCI-E, SATA, PATA, SCSI, ESDI, and IDE.

FIG. 9 is a diagram illustrating a representation of an example of a computing system according to an embodiment.

Referring to FIG. 9, a computing system 1200 according to an embodiment may include a CPU 1220, a RAM 1230, a user interface 1240, a modem 1250, and a memory system 1210. The CPU 1220, RAM 1230, user interface 1240, modem 1250, and memory system 1210 may be electrically coupled to a system bus 1260. In an example where the computing system 1200 is a mobile device, the computing system 1200 may further include a battery for supplying an operational voltage to the computing system 1200, an application chip-set, a CMOS image sensor CIS, a mobile DRAM, and the like.

The memory system 1210 may be formed of a memory device 1212 and a memory controller 1211 as previously described with reference to FIG. 8.

As described above, the embodiments have been disclosed in the drawings and the specification. The specific terms used herein are for purposes of illustration, and do not limit the scope of the application. Accordingly, those skilled in the art will appreciate that various modifications and other equivalent examples may be made without departing from the scope and spirit of the application.

What is claimed is:

1. A semiconductor memory device, comprising:
a memory array including memory strings coupled between bit lines and a common source line; and
a peripheral circuit coupled to the memory array through the bit lines, and configured to generate a bit line voltage varied according to a temperature of the memory array and provide the bit line voltage to a selected bit line among the bit lines, and provide a program inhibit voltage to a non-selected bit line during a program operation.

2. The semiconductor memory device of claim 1, wherein when the temperature is equal to or lower than a reference temperature, the peripheral circuit provides a first bit line voltage to the selected bit line, and when the temperature is higher than the reference temperature, the peripheral circuit provides a second bit line voltage larger than the first bit line voltage to the selected bit line during the program operation.

3. The semiconductor memory device of claim 2, wherein the reference temperature is equal to a room temperature.

4. The semiconductor memory device of claim 3, wherein the room temperature includes a range from 20° C. to 25° C.

5. The semiconductor memory device of claim 2, wherein the second bit line voltage is lower than the program inhibit voltage.

6. The semiconductor memory device of claim 2, wherein the first bit line voltage is a ground voltage and the second bit line voltage is greater than 0.1 volts and less than 2 volts.

7. The semiconductor memory device of claim 1, wherein the memory array includes memory cells serially coupled in a unit of the memory strings and arranged in first to third directions.

8. The semiconductor memory device of claim 7, wherein each of the memory strings includes:
a drain select transistor coupled to any one of the bit lines;
a source select transistor disposed on the same plane as the drain select transistor, and coupled to the common source line;
a pipe transistor disposed on a different plane from that of the drain select transistor and the source select transistor;
a drain side string including drain side memory cells serially coupled between the pipe transistor and the drain select transistor; and
a source side string including source side memory cells serially coupled between the pipe transistor and the source select transistor.

9. The semiconductor memory device of claim 7, wherein each of the memory strings includes:
a drain select transistor coupled to any one of the bit lines;
a source select transistor disposed on a different plane from that of the drain select transistor, and coupled to the common source line; and
less than all of the memory cells serially coupled between the drain select transistor and the source select transistor.

10. The semiconductor memory device of claim 1, wherein the peripheral circuit includes a page buffer circuit, the page buffer circuit including:
page buffers, each page buffer coupled to a bit line among the bit lines and including a precharge unit; and
a temperature sensing circuit coupled to all of the page buffers and configured to sense the temperature of the memory array and generate temperature sensing information,
wherein the temperature sensing information generated by the temperature sensing circuit is supplied to each of the precharge units of each of the page buffers.

11. A programming method of a semiconductor memory device, comprising:
providing a memory array including memory strings coupled between bit lines and a common source line;
sensing a temperature of the memory array; and
generating a bit line voltage according to the sensed temperature and applying the bit line voltage to a selected bit line among the bit lines.

12. The programming method of claim 11, wherein the bit line voltage includes:
a first bit line voltage generated when the temperature is equal to or lower than a reference temperature; and
a second bit line voltage generated to be higher than the first bit line voltage when the temperature is higher than the reference temperature.

13. The programming method of claim 12, wherein the reference temperature is equal to a room temperature.

14. The programming method of claim 12, wherein the first bit line voltage is a ground voltage and the second bit line voltage is greater than 0.1 volts and less than 2 volts.

15. The programming method of claim 13, wherein the room temperature includes a range from 20° C. to 25° C.

16. The programming method of claim 11, wherein a program inhibit voltage is applied to a non-selected bit line among the bit lines during the application of the bit line voltage to the selected bit line.

17. The programming method of claim 16, wherein the bit line voltage is lower than the program inhibit voltage.
